(19) United States
(12) Patent Application Publication
(10) Pub. No.: US 2006/0017592 A1
(43) Pub. Date: Jan. 26, 2006

(54) Method of context adaptive binary arithmetic coding and apparatus using the same

(75) Inventors: Woo-sung Shim, Suwon-si (KR); Austin Lobo, Suwon-si (KR); Jung-woo Kim, Seoul (KR)

Correspondence Address: STAAS & HALSEY LLP, SUITE 700, 1201 NEW YORK AVENUE, N.W., WASHINGTON, DC, 20005, US

(73) Assignee: Samsung Electronics Co., Ltd., Suwon-si (KR)

(21) Appl. No.: 11/106,638

(22) Filed: Apr. 15, 2005

(30) Foreign Application Priority Data
Jul. 22, 2004 (KR) 10-2004-0057161

(51) Int. Cl. H03M 7/00

(52) U.S. Cl. 341/50

(57) ABSTRACT

There are provided a method of context adaptive binary arithmetic coding (CABAC) and an apparatus of the same. The CABAC method includes generating a plurality of syntax elements respectively corresponding to a plurality of predetermined sized residual blocks included in an input block; grouping flags of each of the residual blocks which indicate whether a non-zero transform coefficient exists among the syntax elements; and context adaptive binary arithmetic coding the grouped flags. The complexity of context adaptive binary arithmetic coding is reduced, thereby performing context adaptive binary arithmetic coding more quickly and easily.

### CROSS-REFERENCE TO RELATED APPLICATION

This application claims the benefit of Korean Patent Application No. 10-2004-0057161, filed on Jul. 22, 2004, in the Korean Intellectual Property Office, the disclosure of which is incorporated herein in its entirety by reference.

### BACKGROUND OF THE INVENTION

1. Field of the Invention

The present invention relates to context adaptive binary arithmetic coding (CABAC), and more particularly, to a method which can more easily and quickly perform context adaptive binary arithmetic coding and an apparatus using the same.

2. Description of the Related Art

Since moving images contain a large amount of data, compression coding is required to store or transmit image data. Coding or decoding of image data is performed in units having varying sizes, for example, a macro block having 16×16 pixels or a block having 8×8 pixels.

On the other hand, a new video compression coding standard called MPEG-4 Part 10 advanced video coding (AVC) or ITU-T H.264 has been developed. As a new communication channel used, for example, in a mobile communication network was supplied, H.264 was developed in order to switch a conventional circuit switching system to a packet switching system and to cope with varied communication infrastructures.

H.264 is a video compression coding standard having a coding efficiency that is 50% greater than MPEG-4 Part 2, a conventional standard. Considering the rapidly changing wireless environment and Internet environment, H.264 is robust against errors and is now starting to see wide spread use in networks.

H.264 employs various data compression methods for image data compression. One of the data compression methods is context adaptive binary arithmetic coding (CABAC). CABAC is a method of entropy encoding, which compresses data using symbol occurrence probability.

FIG. 1 is a block diagram of a conventional CABAC encoding apparatus. The CABAC apparatus of FIG. 1 operates according to the H.264 standard. The CABAC apparatus includes a binary coding unit 110, a context modeling unit 130, a probability accounting unit 150, a first binary arithmetic coding unit 160, and a second binary arithmetic coding unit 170.

The binary coding unit 110 performs conventional variable length coding, i.e., it outputs a binary value corresponding to an inputted symbol, referring to a predetermined variable length coding table which is previously stored. The context modeling unit 130 stores a plurality of probability tables, selects a probability table and uses the selected probability table to arithmetically code the binary value received from the binary coding unit 110, and outputs an index value to the probability accounting unit 150.

The probability accounting unit 150 determines the probability value of symbols used for arithmetic coding, referring to the index value of the probability table inputted from the context modeling unit 130. The probability accounting unit 150 outputs the probability value of the symbols and the binary value output from the binary coding unit 110 to the first binary arithmetic coding unit 160. The first binary arithmetic coding unit 160 receives the probability value of the symbols and the binary value output from the binary coding unit 110 to generate a bit stream.

On the other hand, if an inputted symbol does not require a context modeling process, the inputted symbol is provided to the second binary arithmetic coding unit 170 after being binary coded by the binary coding unit 110.

According to the H.264 standard, a residual block and information of motion estimation information are CABACed by the apparatus of FIG. 1, thereby generating a final bit stream. The residual block includes a difference between pixel values of an original block and pixel values of a regeneration block. The regeneration block obtains a motion vector via estimating motion of the original block and regenerates the original block using the obtained motion vector.

H.264 performs discrete cosine transform (DCT) on 4×4 residual blocks and generates each of a plurality of syntax elements as 4×4 residual blocks. The syntax elements of the 4×4 residual blocks, which are defined by H.264 as coded_block_flag, significant_coeff_flag[i], and coeff_sign_flag[i]. The element coded_block_flag indicates whether a non-zero transform coefficient value exists among 16 pixel values of a present 4×4 residual block. The element significant_coeff_flag[i] indicates whether a transform coefficient value of i-th pixel of 16 pixel positions is 0. The element coeff_sign_flag[i] indicates a sign of a transform coefficient value of an i-th pixel, which is not 0. The elements coded_block flag, the significant_coeff_flag[i], and the coeff_sign_flag[i] have lengths of 1 bit, respectively.

When the conventional CABAC described above is performed, a context modeling process performed by the context modeling unit 130 is very complicated. Particularly, a bottleneck situation occurs in the entire CABAC process, caused by a context modeling process of the element coded_block_flag of syntax elements of the 4×4 residual blocks described above.

FIG. 2 is a flow chart illustrating a process of coding syntax elements of one of the sixteen 4×4 blocks included in a present macroblock. After performing DCT on one of the 4×4 blocks and after the syntax elements described above are generated, 1 bit of the element coded_block_flag is encoded (S210). Next, when the value of the element coded_block_flag is “1” (S230), the rest of the syntax elements of the 4×4 blocks are encoded (S250). Here, the encoding includes CABAC.

In the 4×4 blocks, the elements significant_coeff_flag and coeff_sign_flag are allotted to each pixel by 1 bit, and thus, each have a maximum length of 16 bits. In S250, the 16 significant_coeff_flag elements and the 16 coeff_sign_flag elements generated in one of the 4×4 blocks are grouped by the same kind of information and then encoded. On the other hand, in each of the sixteen 4×4 blocks included in the present macroblock, 16 sixteen coded_block_flags are generated but are not grouped and encoded, thereby causing a bottleneck situation in the entire CABAC process.

### SUMMARY OF THE INVENTION

Additional aspects and/or advantages of the invention will be set forth in part in the description which follows and, in part, will be apparent from the description, or may be learned by practice of the invention.

The present invention provides a method and apparatus in which the complexity of context adaptive binary arithmetic coding is reduced to easily and more quickly perform context adaptive binary arithmetic coding.

According to an aspect of the present invention, there is provided a context adaptive binary arithmetic coding method including the operations of: generating a plurality of syntax elements respectively corresponding to a plurality of predetermined sized residual blocks included in an input block; grouping flags of each of the residual blocks which indicate whether a non-zero transform coefficient exists among the syntax elements; and context adaptive binary arithmetic coding the grouped flags.

According to another aspect of the present invention, there is provided a context adaptive binary arithmetic coding apparatus including: a control unit which generates a plurality of syntax elements respectively corresponding to a plurality of predetermined sized residual blocks included in an input block, groups flags of each of the residual blocks which indicate whether a transform coefficient which is not “0” exists among the syntax elements, and outputs the grouped flags; and a context adaptive binary arithmetic coding unit which context adaptive binary arithmetic codes the grouped flags.

According to still another aspect of the present invention, there is provided a computer readable recording medium in which a program executing a context adaptive binary arithmetic coding method is recorded, the method including the operations of: generating a plurality of syntax elements respectively corresponding to a plurality of predetermined sized residual blocks included in an input block; grouping flags of each of the residual blocks which indicate whether a non-zero transform coefficient exists among the syntax elements; and context adaptive binary arithmetic coding the grouped flags.

### BRIEF DESCRIPTION OF THE DRAWINGS

These and/or other aspects and advantages of the invention will become apparent and more readily appreciated from the following description of the embodiments, taken in conjunction with the accompanying drawings of which:

FIG. 1 is a block diagram of a conventional context adaptive binary arithmetic coding (CABAC) apparatus;

FIG. 2 is a flow chart illustrating a process of coding syntax elements of one of a plurality of 4×4 blocks included in a present macroblock;

FIG. 3 is a block diagram of a CABAC apparatus according to an embodiment of the present invention; and

FIG. 4 is a flow chart illustrating a CABAC method according to an embodiment of the present invention.

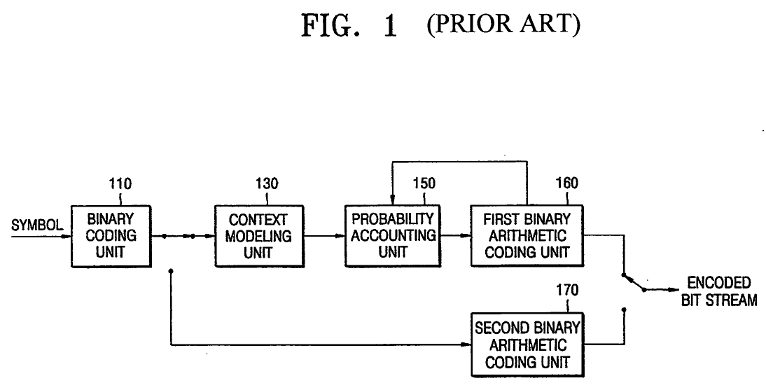

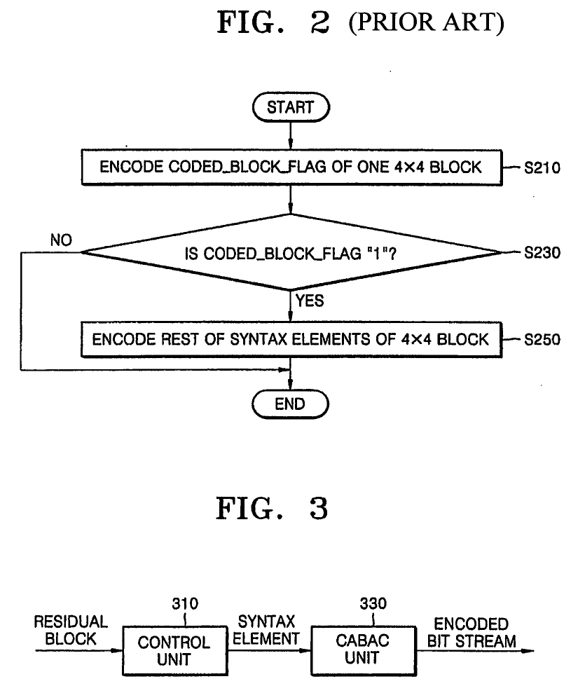

### DETAILED DESCRIPTION OF THE PREFERRED EMBODIMENTS

Reference will now be made in detail to the embodiments of the present invention, examples of which are illustrated in the accompanying drawings, wherein like reference numerals refer to the like elements throughout. The embodiments are described below to explain the present invention by referring to the figures.

In order to solve the problems of the conventional art, according to an embodiment of the present invention, coded_block_flag generated one by one by 4×4 residual blocks are grouped in units of residual macroblocks and encoded together.

FIG. 3 is a block diagram of a context adaptive binary arithmetic coding (CABAC) apparatus according to an embodiment of the present invention. Referring to FIG. 3, the CABAC apparatus includes a control unit 310 and a CABAC unit 330.

When performing discrete cosine transformation (DCT) on a present residual macroblock in units of 4×4 residual blocks is finished, the control unit 310 receives DCT coefficient values of the 4×4 residual blocks and generates a plurality of syntax elements for each of the 4×4 residual blocks. The syntax elements are coded_block_flag, significant_coeff_flag[i], coeff_sign_flag[i], last_significant_coeff_flag[i], and coeff_abs_level_minus_{—}1[i]. The element coded_block_flag indicates whether a non-zero transform coefficient value exists among 16 pixel values of a present 4×4 residual block. The element significant_coeff_flag[i] indicates whether a transform coefficient value of an i-th pixel among 16 pixel positions is 0. The element coeff_sign_flag[i] indicates the sign of a transform coefficient value of an i-th pixel that is not 0. The element last_significant_coeff_flag[1] indicates whether an i-th pixel among 16 pixel positions is the last non-zero transform coefficient. The element coeff_abs_level_minus_{—}1[i] indicates a value, which is obtained by subtracting 1 from the absolute value of the last non-zero transform coefficient of the i-th pixel.

The element coded_block_flag, the element significant_coeff_flag[i], the element coeff_sign_flag[i], and the element last_significant_coeff_flag[i] each have length of 1 bit. The length of coeff_abs_level_minus_{—}1[i] varies according to the type of value.

The control unit 310 groups a plurality of the coded_block_flag syntax element and outputs the grouped flags to the CABAC unit 330.

The CABAC unit 330 receives the grouped flags and performs CABAC on them. Then, the CABAC unit 330 receives the rest of a plurality of the syntax elements and performs CABAC on them.

A CABAC method according to an embodiment of the present invention will now be described in detail based on the configuration of the CABAC apparatus of FIG. 3.

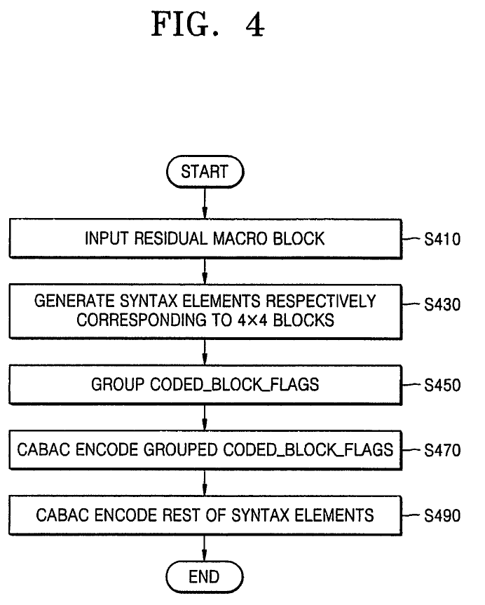

FIG. 4 is a flow chart illustrating the CABAC method according to an embodiment of the present invention.

In an embodiment of the present invention, an entire encoding process is performed in units of 16×16 sized macroblocks. The DCT and the generation of the syntax elements for residual data such as coded_block_flag, significant_coeff_flag[i], last_significant_coeff_flag[i], coeff_abs_level_minus_{—}1[i], and coeff_sign_flag[i] are performed in units of 4×4 blocks.

When performing the DCT on the present residual macroblock in units of the 4×4 residual blocks is finished, the control unit 310 receives DCT coefficient values of the 4×4 residual blocks (S410) and generates syntax elements such as coded_block_flag, significant_coeff_flag[i], last_significant_coeff_flag[i], coeff_abs_level_minus_{—}1[i], and coeff_sign_flag[i] (S430).

Since the present residual macroblock includes sixteen 4×4 luma residual blocks, one 4×4 luma DC residual block, two 2×2 chroma DC residual blocks, and eight 4×4 chroma AC residual blocks, the elements coded_block_flag of the present macroblock have a maximum value of 27. The control unit 310 groups a plurality of the coded_block_flags (S450).

The control unit 310 outputs the grouped coded_block_flags to the CABAC unit 330. The CABAC unit 330 receives the grouped coded_block_flags and performs CABAC on them (S470). According to a conventional art, the coded_block_flag elements are not grouped and separated and encoded by 1 bit, thereby increasing the complexity of the CABAC process. However, according to the present invention, a plurality of coded_block_flag elements of the present macroblock are grouped together and the CABAC is performed together, thereby reducing the complexity of the CABAC process.

On the other hand, in a context modelling process, the most proper probability table for the CABAC of an input symbol, the coded-block_flag, is selected from a plurality of probability tables. In order to select the most proper probability table for the CABAC of the input symbol, pattern information of blocks located around the present 4×4 residual blocks and information of the syntax elements such as coded_block_flag are required. Reference blocks for context modelling the element coded_block_flag related to the present 4×4 residual blocks are 4×4 blocks above the present 4×4 residual blocks, 4×4 blocks to the left of the present 4×4 residual blocks, a macroblock above the present residual macroblock in which the present 4×4 residual blocks are included, and macroblocks to the left of the present residual macroblock.

Accordingly, when the coded_block_flags are not grouped and are separated from each other by 1 bit to perform the CABAC according to a conventional art, for the context modelling process, the pattern information and information of the syntax elements such as coded_block_flag of the 4×4 blocks above the present 4×4 residual blocks, the 4×4 blocks to the left of the present 4×4 residual blocks, the macroblock above the present residual macroblock in which the present 4×4 residual blocks are included, and the macroblock to the left of the present residual macroblock are retrieved and read. However, according to the present invention, a plurality of coded_block_flag elements related to the present macroblock is grouped and are CABACed together, thereby reducing the complexity of the context modelling process. For example, the pattern information and information of the syntax elements such as the coded_block_flag of the macroblock above the present residual macroblock and the macroblock to the left of the present residual macroblock are retrieved, read, and stored once. Therefore, there is no need to retrieve and read such information each time.

After the CABAC unit 330 performs CABAC on the grouped coded_block_flag elements according to S470, the rest of the syntax elements except the coded_block_flag elements are inputted from the control unit 310 to be CABACed (S490).

As described above, in an embodiment of the present invention, as an example, 16×16 macroblocks are inputted to DCT in units of 4×4 blocks, and syntax elements are encoded. However, the size of a block is not restricted to 16×16 macroblocks or 4×4 blocks. It is understood that macroblocks can be M×N macroblocks (M=N or M≠N, positive integer), or macroblocks can be any predetermined shape, and changes may be made accordingly without departing from the principles of the invention.

The invention can also be embodied as computer readable codes on a computer readable recording medium. The computer readable recording medium is any data storage device that can store data which can be thereafter read by a computer system. Examples of the computer readable recording medium include read-only memory (ROM), random-access memory (RAM), CD-ROMs, magnetic tapes, floppy disks, optical data storage devices, and carrier waves (such as data transmission through the Internet). The computer readable recording medium can also be distributed over network coupled computer systems so that the computer readable code is stored and executed in a distributed fashion.

While the present invention has been particularly shown and described with reference to exemplary embodiments thereof, it will be understood by those of ordinary skill in the art that various changes in form and details may be made therein without departing from the spirit and scope of the present invention as defined by the following claims.

Although a few embodiments of the present invention have been shown and described, it would be appreciated by those skilled in the art that changes may be made in these embodiments without departing from the principles and spirit of the invention, the scope of which is defined in the claims and their equivalents.

1. A coding method comprising:
generating a plurality of syntax elements of residual block(s);
grouping flags of the plurality of syntax elements; and
coding the grouped flags.

2. The method of claim 1, further comprising: coding the plurality of syntax elements except the grouped flags.

3. The method of claim 1, wherein the residual block(s) comprises a 4×4 pixel block.

4. The method of claim 1, wherein the coding is context adaptive binary arithmetic coding.

5. The method of claim 1, wherein the residual block comprises a M×N pixel block.

6. The method of claim 1, wherein M=N and M and N are integers.

7. The method of claim 1, wherein the flag indicating whether a non-zero transform coefficient exist among the syntax elements.

8. The method of claim 1, wherein the residual block comprises a macro block.

9. The method of claim 8, wherein the macro block comprises a K×L macro block.

10. The method of claim 9, wherein K=L and K and L are integers.

11. The method of claim 9, wherein the K×L macro block is a 16×16 macro block.

12. A coding apparatus comprising:
a control unit which generates a plurality of syntax elements corresponding to a plurality of residual blocks, and groups flags of each of the residual blocks; and
a coding unit which codes the grouped flags.

13. The apparatus of claim 12, wherein coding unit receives the rest of a plurality of the syntax elements except the flags and codes the rest of the syntax elements.

14. The apparatus of claim 12, wherein the residual block comprises a 4×4 pixel block.

15. The apparatus of claim 12, wherein the coding is a context adaptive binary arithmetic coding.

16. The apparatus of claim 12, wherein the residual block comprises an M×N pixel block.

17. The apparatus of claim 16, wherein M and N are integers and M=N.

18. The apparatus of claim 12, wherein the flags indicating whether a non-zero transform coefficient exist among the syntax elements.

19. The method of claim 12, wherein the residual block comprises a macro block.

20. The method of claim 19, wherein the macro block is a K×L macro block.

21. The method of claim 20, wherein K and L are integers and K=N.

22. The method of claim 20, wherein the K×L macro block is a 16×16 macro block.

23. A computer readable recording medium controlling a computer and executing a context adaptive binary arithmetic coding method, the method comprising:
generating a plurality of syntax elements respectively corresponding to a plurality of predetermined sized residual blocks;
grouping flags of each of the residual blocks which indicate whether a non-zero transform coefficient exists among the syntax elements; and
context adaptive binary arithmetic coding the grouped flags.

24. The computer readable recording medium controlling a computer and executing a context adaptive binary arithmetic coding method is recorded, the method further comprising the operation of context adaptive binary arithmetic coding the rest of a plurality of the syntax elements except the flags after the operation of context adaptive binary arithmetic coding the grouped flags.

25. The computer readable recording medium of claim 24 in which a program executing a context adaptive binary arithmetic coding method is recorded, wherein the residual block is a 4×4 pixel block.
